(19) United States
(12) Patent Application Publication
(10) Pub. No.: US 2026/0235390 A1
(43) Pub. Date: Aug. 13, 2026

(54) SIGNAL PROCESSING METHOD, SENSOR AND USE OF A SENSOR FOR DETERMINING ROTATIONAL SPEEDS AND/OR ROTATIONAL POSITIONS OF WHEELS OF RAIL VEHICLE

(71) Applicant: KNORR-BREMSE SYSTEME FÜR SCHIENENFAHRZEUGE GMBH, Munich (DE)

(72) Inventors: Robert KAKONYI, Kalocsa (HU); Imre BUSZNYAK, Budapest (HU)

(21) Appl. No.: 19/153,201

(22) PCT Filed: Jan. 16, 2024
(86) PCT No.: PCT/EP2024/050904

§ 371 Date: Aug. 1, 2025

(30) Foreign Application Priority Data
Feb. 2, 2023 (EP) 23154629.2

(51) Int. Cl. G01B 7/30; B60T 17/22; B61K 9/02; F16D 66/00; G01D 5/20; G01R 31/72

(52) U.S. Cl. CPC G01B 7/30; B60T 17/228; B61K 9/02; F16D 66/00; G01D 5/20; G01R 31/72; B60T 2240/00; F16D 2066/003; F16D 2066/006

(57) ABSTRACT

A signal processing method and a sensor use a first winding provided on a wheel, wherein the first winding includes any angle with a reference position, a second winding, and a third winding, wherein the directions of the second winding, and a third winding are not parallel; a signal generation and processing unit configured to provide an AC voltage to the first winding and to receive the a first induced voltage of the second winding and the second induced voltage of the third winding. With such a system, wheel speeds/positions can be measured very accurately.

### PRIORITY CLAIM AND CROSS REFERENCE

This patent application is a U.S. National Phase of International Patent Application No. PCT/EP2024/050904 filed Jan. 16, 2024, which claims priority to European Patent Application No. 23154629.2, the disclosure of which being incorporated herein by reference in their entireties.

### FIELD

Disclosed embodiments deal with a diagnostic system for a rail vehicle, with a fast and robust wheel speed and position calculation.

### BACKGROUND

From prior art, document EP 3 963 617 A1 is known.

### SUMMARY

Disclosed embodiments provide a signal processing method and a sensor which are able to precisely measure rotation speeds and/or rotation positions for wheels, in particular wheels of train vehicles.

### BRIEF DESCRIPTION OF THE FIGURES

Disclosed embodiments are described by appended figures, wherein:

FIG. 1 shows a schematic view of a sensor according to a disclosed embodiment.

FIG. 2 shows a schematic view of a sensor according to another disclosed embodiment.

### DETAILED DESCRIPTION

For certain applications of rail vehicles, the wheel speed and the wheel position have to be determined very accurately. Such systems contain a motor for driving a drive shaft, and also a feedback system which is designed to determine at least one new value for the precision of the drive shaft and to generate feedback signal based on the at least one value. A controller is designed to influence the operation of the motor based on the feedback signal. The motor can be used for various applications.

For example, in a wheel slide protection system of a train including single vehicles, a system using a pole-wheel-based encoder works well according to EN norms. However, such pole-wheel-based encoder has certain limitations.

At first, such a system does not detect the direction of rotation, which may lead to challenges to obtain directional information for certain applications.

Further, the signal quality can depend on the actual speed of the train. Below 3 km/h, the vehicle speed signal can be unreliable or even unavailable. However, such information has to be available for precision stopping performed by braking, in particular for metro stations with doors on the platform.

Furthermore, if the latency of the signal processing is too large, fast interventions (e.g. targeted use of a microslip or keeping the slip value at a maximum of the adhesion growth) cannot be used. However, a lower latency is desired, which leads to more precise control and a more reproducible brake distance.

Furthermore, if the train starts from a standstill, the torque control can be very challenging due to slipping wheels. However, also such applications can benefit from better latency performance.

In recent developments, electromechanical actuators are becoming more popular. For example, they do not need an air supply to be operable.

Furthermore, for electromechanical actuators, the latency of actuation is also lower. The total latency of the brake system (speed detection, signal processing, control decision, actuation) can be decreased significantly. However, the limiting factor is the speed sensor.

Also, an automatic train operation becomes more popular, however has very strict requirements with regard to the stopping positions. Such automatic train operation requires a high-quality speed signal in case of slow-moving wheels. As an example, with numerical parameters of the current design: the path length passed by the train can be 0.62 m if the deceleration is 0.8m/s2, and the starting speed is 1 m/s (this is a typical specification).

If the stopping is only controlled by one brake unit, a certain distance (until standstill) shall be passed by the train in a practical blind mode. This is the main disadvantage of precision stopping only by a brake. In current state of the art one possible implementation of the precision stopping is combined usage of the traction and brake system of the train. Brake systems can be commanded for certain amount of brake force interaction used for precise control in the final position and the traction is controlled to achieve the desired stopping position, however, in such a case, the wear of the brake system becomes significant, and a lot of energy can be consumed.

Hence, the technical problem to be solved by the presently disclosed embodiments can be seen in providing a signal processing method and a sensor which are able to precisely measure rotation speeds and/or rotation positions for wheels, in particular wheels of train vehicles.

A signal processing method for determining an angular position, in particular, for a wheel of the rail vehicle, includes the following operations:
a) Excitation of a first winding by an AC voltage, the first winding being provided on a wheel, wherein the first winding can include any angle with a reference position;
b) Measuring a first induced voltage in a second winding, and delivering the induced voltage to a signal generation and processing unit;
c) Measuring a second induced voltage in a third winding, and delivering the induced voltage to a signal generation and processing unit;
d) Determining a rotation angle of the wheel in the signal generation and processing unit;
e) Calculating a rotation speed and/or rotation position of the wheel.

The middle axes of the second winding and the third winding are not parallel in order to be able to measure two different induced voltages.

The second winding and the third winding are positioned beside the wheel.

With such system, very precise positions of a wheel can be obtained, in particular the brake performance of a train can be significantly improved, and real-time online track diagnostics are possible. The rotation speed and the rotation position of the wheel can be calculated very easily, as—for the case of the middle axes of the second winding and the third winding being orthogonal—the first induced voltage provides a sine signal, and the second induced voltage provides a cosine signal. The induced voltages in the first winding and the second winding are equal to the value of the reference voltage (induced voltage) multiplied by the sine or cosine of the angle of the wheel from a fixed reference point. The sensor provides two voltages the ratio of them represents the absolute position of the input shaft (sin θ/cos θ=tan θ, where θ is the shaft angle). The advantage of the sine/cosine ratio is that the shaft angle is absolute. Even if the shaft is rotated during a power loss, the resolver can report its new position value when power is restored.

Furthermore, such application leads to a low latency, which leads to a low latency electromechanical brake actuator being the prerequisite for precision stopping performed only by the brake system. The reproducibility of the brake distance is improved due to the lower latency closed loop control system driven by the absolute position of the vehicle. A lower performance or lower parameter stability of the used materials of the pad and the disc of a brake can be compensated to have the same braking performance even with cheaper materials.

Furthermore, the higher time resolution and the low latency of the wheel speed/position sensor enables tracking diagnostics without affecting the brake distance of the vehicle. The adhesion curve (friction coefficient between the wheel and rail as a function of wheel slip) can be measured or even derived during operational braking or test braking. Test braking can be initiated by a driver. The measured adhesion curve can be reported to the operator, who can then decide if there is any need for track cleaning. During operational braking, an artificial wheel slip event can be generated to record the rotation speed profile of the wheel and derive the adhesion curve. The sensor arrangement according to disclosed embodiments can even be installed as additional feature to an existent pole-wheel-based encoder.

The signal generated by the sensor arrangement according to the disclosed embodiments can be compared in real time with the signal of a pole-wheel sensor, thus the new technology can be validated in real time without affecting the safety of the vehicle in retrofit. The signal of the sensor arrangement according to the disclosed embodiments can be effectively used for a limited number of specific applications, and in particular precision stopping and adhesion measurement. Also, speed information of below 3 km/h can be made available, and such speeds frequently occur when a braking of a system occurs.

The above-described sensor is optionally a resolver. Resolvers, being a very specific sensor type, have a wide range of use in various applications, in particular if environmental conditions are harsh. Resolvers are very robust sensors and are able to provide precise angular positions in the milliradian resolution. Dependent on the signal processing algorithm, the output of the sensor can be the rotation speed and/or the rotation position. The precise output can be beneficial for precise stopping functionality, as for achieving a 1 cm position resolution, a 3.2 MRAD angular resolution is required for a 0.5 m wheel radius.

Optionally, the excitation current is provided by the signal generation processing unit, filtered by a first filter, and delivered to the first winding in operation a).

The filter has the functionality of high voltage protection of the signal generation and processing unit. The filter block can also implement bandpass filtration to eliminate any DC offsets from the measured or generated signals.

Hence, also the first induced voltage can be filtered by a second filter, optionally, before being delivered to the signal generation processing unit. The same being true for the second induced voltage, which is filtered by a third filter before being delivered to the signal generation and processing unit.

Optionally, the excitation of the first winding by an AC voltage is performed with more than one frequency. This makes the whole sampling more robust.

Optionally, the excitation of the first winding by an AC voltage is performed with more than one frequencies to estimate the axle or wheel speed/axle or wheel position and another number of frequencies to search for less noisy frequency ranges. This also results in very robust signal processing.

Optionally, the sampling frequency of the evaluation of the first induced voltage and the second induced voltage is approximately two times the excitation frequency of the excitation current. Hence, a leakage effect to the FFT algorithm used by the signal generation and processing unit can be avoided. The excitation for sampling can then be precisely synchronized.

Optionally, the evaluation algorithm is a correlation search after Fourier transformation of the first and second and third winding channels. Hence, frequency ranges with lowest external noise disturbances can be used.

Also, a degraded mode is possible, which further increases the safety if a part of the wires breaks, the signal processing method can switch to a single component mode. The position and the speed can be sampled by using one channel, which means only the second winding or third winding. If the excitation line (first winding) breaks, then the coupling of the first winding and second winding channels can be utilized to estimate the axial position or speed with degraded mode with lower performance.

Optionally, the signal processing method includes the two following further operations:
f) Performing a braking of the wheel;
g) Measuring the velocity of the whole vehicle, and calculating the slip of the wheel based on the rotation speed of the wheel and the velocity of the whole vehicle.

Herein, a slip behavior of the wheel can be determined, and the adhesion curve (friction coefficient between the wheel and track as a function of wheel slip) can be measured or derived during the operational braking or testing.

Optionally, the middle axes of the second winding and the third winding are almost orthogonal, and optionally orthogonal. Such configuration makes signal generation very robust. The angle calculation is hence performed using the projections of a rotating vector. If the components are not perpendicular, calculation can be still performed, but the performance would be expectedly lower.

Optionally, the coil checking unit communicates with the signal generation and processing unit via protected data line and transfers diagnostic information, the diagnostic information being used for selecting a suitable signal processing depending on the availability of the first winding, the second winding and/or the third winding. If one of the windings is broken, the signal generation and processing unit can perform the signal processing via another method which does not need the broken winding. Such alternative signal processing might be less precise, but a complete failure of the wheel speed and position detection can be avoided. This is advantageous regarding safety issues, in particular when being used in a brake system.

Optionally, the signal generation and processing unit provides a quality parameter output signal which describes the reliability of the position and speed signals in real time. This even more advantageous regarding safety issues. A sensor according to the disclosed embodiments may include a first winding being provided on a wheel, wherein the first winding can include any angle with a reference position; a second winding, and a third winding, wherein the directions of the second winding, and a third winding are not parallel; a signal generation and processing unit, adapted to provide an AC voltage to the first winding and to receive the first induced voltage of the second winding and the second induced voltage of the third winding.

Optionally, a rotary transformer is provided between the signal generation and processing unit and the first winding. The rotary transformer is a functional unit to forward the excitation signal from the static part to the axle-mounted rotating excitation coil of the sensor. This can provide a higher precision compared to e.g. a carbon brush, as there is no wear effect.

Optionally, a first filter is provided somewhere between the signal generation and processing unit and the first winding. Optionally, a second filter is provided between the signal generation and processing unit and the second winding, and/or a third filter is provided between the signal generation and processing unit and the third winding. These filters have the following advantages: The signal generation and processing can be protected from higher overvoltage overloads, and furthermore, different signal filtering features can be implemented, by passing only the frequencies used by the system for excitation of the sensor. The biggest disturbance of the sensor signal and processing unit is an EMC signal from higher voltage power supply for the train or another train passing on the parallel track. The inventive sensor arrangement has a safety-related function of the brake system, as it ensures by performing of filtering that only values which are relevant for the wheel to be observed are used.

Optionally, the first filter, the second filter and/or the third filter is/are adapted to implement bandpass filtration in order to eliminate any DC offsets from the measured or generated signals. This makes the measurement more robust.

Optionally, a wire and coil checking unit is provided, which is adapted to check if wires or the windings are broken. If the wire of the second winding and/or the third winding is broken, then signal generation and processing unit can switch to a single secondary winding-based signal processing method. If the first winding is broken, then one of the second winding or third winding is used to provide the excitation signal, and the signal processing unit is switched to a different signal processing method to obtain speed and position information.

The disclosed brake system for a rail vehicle may include a sensor arrangement as described above.

Optional uses of the sensor according to the disclosed embodiments are for determining rotational speeds and/or rotational positions of a wheel of a rail vehicle, and even for determining wheel slips of wheels of a rail vehicle.

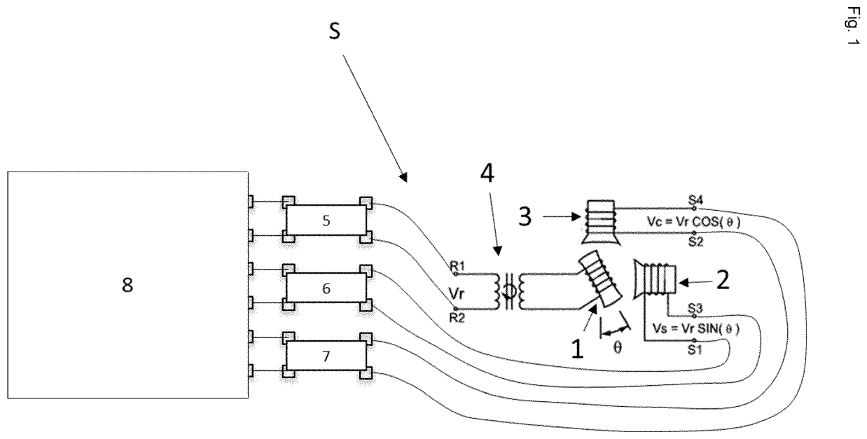

FIG. 1 shows a basic embodiment, wherein a first winding 1 is provided on the wheel W (not shown here) of a rail vehicle, this first winding 1 is connected via a fifth terminal R1 and a sixth terminal R2 to a first filter 5, which is connected with a signal generation and processing unit 8. Between the first winding 1 and the fifth terminal R1 and a sixth terminal R2, a rotary transformer 4 is provided.

Furthermore, a second winding 2 is provided outside of the wheel, by which a sin signal can be measured (Vs=Vr×sin θ), and furthermore, a third winding 3 is provided, which measures a cosine signal (Vc=Vr×cos θ). The second winding 2 is connected with a respective first terminal and third terminal S1 and S3 to a third filter S3, which is again connected to the signal generation and processing unit 8. Also, the third winding 3 is provided with a second and fourth terminal S2 and S4 to a second filter 6, which is connected with the signal generation and processing unit 8.

Hence, separated filters 5, 6, 7 are used for each winding 1, 2, 3. The signal generation and processing unit 8 is the main signal processing unit. It has separate outputs for each winding, i.e. the first winding 1 is a reference winding, the second winding 2 is a sine winding, and the third 3 winding is a cosine winding.

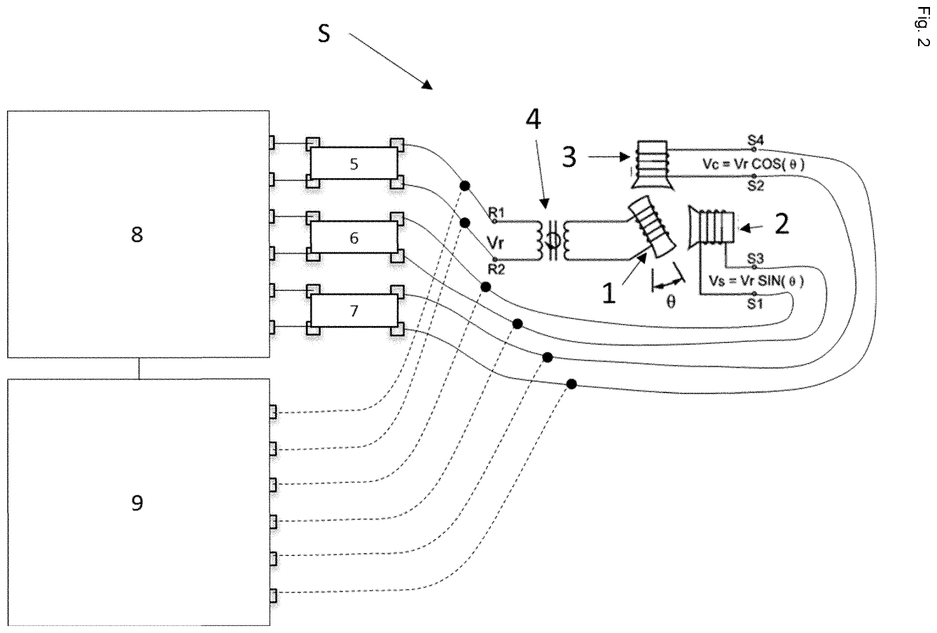

In FIG. 2, a second embodiment is shown. Herein, a wire and coil checking unit 9 is provided. The wire and coil checking unit 9 is a completely separated electronic component which checks that the wires of the first winding 1, second winding 2 and For this purpose, the wire and coil checking unit 9 uses a small DC current. The first filter 1, second filter 2 and third winding 3 are separating the signal generation and processing unit 8 and the wire and coil checking unit 9.

However, the wire and coil checking unit 9 can report to the wire and coil checking unit 9 which line is broken.

If one or more of the wires of one winding (first winding 1, second winding 2 and/or third winding 3) is broken, then the signal generation and processing unit 8 can still operate in a degraded mode. Some speed and position information can be still extracted by neglecting signal from the winding (first winding 1, second winding 2 and/or third winding 3) with broken wire.

If the wire of the excitation winding (second winding 2 and/or third winding 3) is broken, then wire and coil checking unit 9 can switch one of the second winding 2 or third winding 3 to the excitation channel (first winding 1) and switch to a different signal processing method to obtain speed and position information.

Disclosed embodiments, as reasonably understood by one of ordinary skill in the art, are not limited to the embodiment expressly described above. For example, even more windings can be used by the sensor; this would make the sensing even more robust. Also, each angle between the second winding 2 and the third winding 3 can be used—however, the middle axes of the second winding 2 and the third winding 3 cannot be parallel.

### LIST OF REFERENCE SIGNS

S Sensor (resolver)
W Wheel
R Reference position
1 First winding
2 Second winding
3 Third winding
4 Rotary transformer
5 First filter
6 Second filter
7 Third filter
8 Signal generation and processing unit
9 Wire and coil checking unit
S1 First terminal
S2 Second terminal
S3 Third terminal
S4 Fourth terminal
R1 Fifth terminal
R2 Sixth terminal
AC Induced voltage
Vr First induced voltage
Vc Second induced voltage

1. A signal processing method for determining an angular position for a wheel of a rail vehicle, the method comprising:
excitation of a first winding by an AC voltage, the first winding being provided on a wheel of the rail vehicle, wherein the first winding includes any angle with a reference position;
measuring a first induced voltage in a second winding;
delivering the induced voltage to a signal generation and processing unit;
measuring a second induced voltage in a third winding;
delivering the induced voltage to the signal generation and processing unit, wherein the middle axes of the second winding and the third winding are not parallel;
determining a rotation angle of the wheel in the signal generation and processing unit; and
calculating a rotation speed and/or rotation position of the wheel,
wherein the middle axes of the second winding and the third winding are not parallel.

2. The signal processing method of claim 1, further comprising:
providing an excitation current by the signal generation and processing unit;
filtering the excitation current by a first filter; and
delivering the filtered excitation current to the first winding for the excitation of the first winding by AC voltage, and/or
filtering the first induced voltage by a second filter and subsequently delivering the resulting signal to the signal generation and processing unit, and/or
filtering the second induced voltage by a third filter and subsequently delivering the resulting signal to the signal generation and processing unit.

3. The signal processing method of claim 1, wherein the excitation of the first winding by an AC voltage is performed with more than one frequency.

4. The signal processing method of claim 3, wherein the excitation of the first winding by AC voltage is performed with N frequencies to estimate the axle speed/position and M number of frequencies to search for less noisy frequency ranges.

5. The signal processing method of claim 1, wherein a sampling frequency of the evaluation of the first induced voltage and the second induced voltage is approximately two times an excitation frequency of the excitation current.

6. The signal processing method of claim 1, further comprising:
performing a braking of the wheel;
measuring the velocity of the whole rail vehicle; and
calculating slip of the wheel based on the rotation speed of the wheel and the velocity of the whole rail vehicle.

7. The signal processing method of claim 1, further comprising checking, by a wire and coil checking unit, if wires are broken in predetermined intervals.

8. The signal processing method of claim 7, wherein the wire and coil checking unit communicates with the signal generation and processing unit via a protected data line, wherein the method further comprises:
the wire and coil checking unit andtransfers diagnostic information to the signal generation and processing unit; and
selecting a suitable signal processing using the diagnostic information based on the availability of the first winding, second winding and/or third winding.

9. The signal processing method of claim 1, further comprising providing, by the signal generation and processing unit, a quality parameter output signal which describes reliability of position and speed signals in real time.

10. A sensor for determining an angular position for a wheel of a rail vehicle, the sensor comprising:
a first winding provided on the wheel of the rail vehicle, wherein the first winding includes any angle with a reference position;
a second winding; and
a third winding, and
a signal generation and processing unit configured to provide an AC voltage to the first winding and to receive a first induced voltage of the second winding and a second induced voltage of the third winding,
wherein directions of the second winding and the third winding are not parallel.

11. The sensor of claim 10, further comprising a first filter provided between the signal generation and processing unit and the first winding, and/or
a second filter provided between the signal generation and processing unit and the second winding, and/or
a third filter provided between the signal generation and processing unit and the third winding.

12. The sensor of claim 11, wherein the first filter and/or the second filter and/or the third filter is adapted to implement band pass filtration to eliminate any DC offsets from the measured or generated signals.

13. The sensor of claim 10 further comprising a wire and coil checking unit configured to check if wires are broken.

14. A brake system for a rail vehicle, the brake comprising at least one sensor according to claim 10.

15. A method of using a sensor to determine rotational speeds and/or rotational positions of wheels of a rail vehicle and/or for determining wheel slips of wheels of a rail vehicle, wherein the method determines an angular position for a wheel of the rail vehicle using a first winding provided on the wheel of the rail vehicle, wherein the first winding includes any angle with a reference position, a second winding, and a signal generation and processing unit, configured to provide an AC voltage to the first winding and to receive a first induced voltage of the second winding and a second induced voltage of the third winding, wherein directions of the second winding and the third winding are not parallel.
